(19) United States
(12) Patent Application Publication
(10) Pub. No.: US 2004/0217380 A1
(43) Pub. Date: Nov. 4, 2004

(54) Semiconductor device, electronic device, electronic apparatus, method for manufacturing a semiconductor device, and method for manufacturing an electronic device

(76) Inventor: Akiyoshi Aoyagi, Atsugi-shi (JP)

Correspondence Address: HARNESS, DICKEY & PIERCE, P.L.C., P.O. BOX 828, BLOOMFIELD HILLS, MI, 48303, US

(21) Appl. No.: 10/787,060

(22) Filed: Feb. 25, 2004

(30) Foreign Application Priority Data
Feb. 25, 2003 (JP) 2003-047929

(51) Int. Cl. H01L 31/072

(52) U.S. Cl. 257/200

(57) ABSTRACT

A device and method are provided for preventing a protruding electrode from being melted during mounting of a carrier substrate. A first protruding electrode whose melting point is lower than that of a second protruding electrode is provided on a land that is formed on the back surface of a carrier substrate. The first protruding electrode is bonded on a land on a mother substrate by reflow processing at a temperature that is lower than the melting point of the second protruding electrode and higher than the melting point of the first protruding electrode.

### RELATED APPLICATIONS

This application claims priority to Japanese Patent Application No. 2003-047929 filed Feb. 25, 2003 which is hereby expressly incorporated by reference herein in its entirety.

### BACKGROUND

1. Field of the Invention

The present invention relates to a semiconductor device, an electronic device, an electronic apparatus, a method for manufacturing a semiconductor device, a method for manufacturing an electronic device, and more particularly to the multilayered structure of semiconductor packages and the like.

2. Description of the Related Art

To save space when embedding semiconductor chips in a semiconductor device, a conventional method employs three-dimensional packaging of the chips using carrier substrates as disclosed in Japanese Unexamined Patent Application Publication No. 10-284683, for example.

However, there arises a problem with the three-dimensional packaging of semiconductor chips using carrier substrates. During mounting of carrier substrates, a protruding electrode for joining the substrates is melted, and thereby the package is deformed.

In consideration of this problem, the present invention aims to provide a semiconductor device, an electronic device, an electronic apparatus, a method for manufacturing a semiconductor device, and a method for manufacturing an electronic device all of which are able to prevent the deformation of a protruding electrode during mounting of carrier substrates.

### SUMMARY

To address the above-mentioned problem, a semiconductor device according to an aspect of the invention includes a first semiconductor package that includes a first semiconductor chip, a first protruding electrode that is provided to the first semiconductor package, and a second semiconductor package that includes a second semiconductor chip, and is mounted on the first semiconductor package via a second protruding electrode whose melting point is higher than that of the first protruding electrode.

This makes it possible to prevent the second protruding electrode, which is bonded to the first semiconductor package, from being melted during mounting of the first semiconductor package via the first protruding electrode. Therefore, the deformation of semiconductor packages is prevented during the three-dimensional packaging of semiconductor chips. Accordingly, it is possible to save space when mounting semiconductor chips, as well as provide a reliable multi-layered structure of the semiconductor chips.

In a semiconductor device according to an aspect of the invention, the first semiconductor package also includes a first carrier substrate on which the first semiconductor chip is mounted. The second semiconductor package also includes a second carrier substrate that is mounted on the first carrier substrate via the second protruding electrode so as to lay the second carrier substrate on the first semiconductor chip.

This makes it possible to mount the first semiconductor package on the second semiconductor package to form a multi-layered structure without increasing the height of the structure, even if the first and second semiconductor packages are different types. This further enables more reliable joining in mounting of a semiconductor device.

In a semiconductor device according to an aspect of the invention, the first semiconductor package also includes a ball grid array package having the first semiconductor chip that is flip-chip mounted on the first carrier substrate. The second semiconductor package also includes a ball grid array package or a chip size package having the second semiconductor chip that is mounted and sealed by means of molding on the second carrier substrate.

Accordingly, even when using generic packages, it is possible to prevent protruding electrodes from being melted, while forming a multi-layered structure of semiconductor packages that are different types. This enables more reliable joining between semiconductor packages of different types without harming production efficiency.

A semiconductor device according to an aspect of the invention includes a first carrier substrate and a first protruding electrode that is bonded to the first carrier substrate. The semiconductor device also includes a second carrier substrate that is mounted on the first carrier substrate via a second protruding electrode whose melting point is higher than that of the first protruding electrode. The semiconductor device also includes a first semiconductor chip that is mounted on the first carrier substrate via a third protruding electrode whose melting point is higher than that of the second protruding electrode, and a second semiconductor chip that is mounted on the second carrier substrate.

This makes it possible to prevent the second protruding electrode, which is bonded to the first carrier substrate, from being melted during mounting of the first carrier substrate via the first protruding electrode. Furthermore, this also makes it possible to prevent the third protruding electrode, which is bonded to the first carrier substrate, from being melted while mounting the second carrier substrate via the second protruding electrode. Therefore, the deformation of semiconductor packages is prevented during the three-dimensional packaging of semiconductor chips. Accordingly, it is possible to save space when mounting semiconductor chips, as well as provide a reliable multi-layered structure of the semiconductor chips.

An electronic device according to an aspect of the invention includes a first package that includes a first electronic part, and a first protruding electrode that is bonded to the first package. The electronic device also includes a second package that includes a second electronic part, and is mounted on the first package via a second protruding electrode whose melting point is higher than that of the first protruding electrode.

This makes it possible to prevent the second protruding electrode, which is provided to the first package, from being melted during mounting of the first package via the first protruding electrode. Therefore, the deformation of packages is prevented during the three-dimensional packaging of electronic parts.

An electronic device according to an aspect of the invention includes a first carrier substrate and a first protruding electrode that is bonded to the first carrier substrate. The electronic device also includes a second carrier substrate that is mounted on the first carrier substrate via a second protruding electrode whose melting point is higher than that of the first protruding electrode. The electronic device also includes a first electronic part that is mounted on the first carrier substrate via a third protruding electrode whose melting point is higher than that of the second protruding electrode, and a second electronic part that is mounted on the second carrier substrate.

This makes it possible to prevent the second protruding electrode, which is bonded to the first carrier substrate, from being melted during mounting of the first carrier substrate via the first protruding electrode. Furthermore, this also makes it possible to prevent the third protruding electrode, which is bonded to the first carrier substrate, from being melted while mounting the second carrier substrate via the second protruding electrode. Therefore, the deformation of packages is prevented during the three-dimensional packaging of electronic parts.

An electronic apparatus according to an aspect of the invention includes a first semiconductor package that includes a first semiconductor chip, and a first protruding electrode that is bonded to the first semiconductor package. The electronic apparatus also includes a second semiconductor package that includes a second semiconductor chip, and is mounted on the first semiconductor package via a second protruding electrode whose melting point is higher than that of the first protruding electrode. The electronic apparatus also includes a mother substrate on which the first semiconductor package is mounted via the first protruding electrode.

This makes it possible to prevent the second protruding electrode, which is bonded to the first semiconductor package, from being melted during mounting of the first semiconductor package on the mother substrate via the first protruding electrode. Therefore, the deformation of semiconductor packages is prevented during the three-dimensional packaging of semiconductor chips.

An electronic apparatus according to an aspect of the invention includes a first carrier substrate, a first protruding electrode that is bonded to the first carrier substrate, and a second carrier substrate that is mounted on the first carrier substrate via a second protruding electrode whose melting point is higher than that of the first protruding electrode. The electronic apparatus also includes a first semiconductor chip that is mounted on the first carrier substrate via a third protruding electrode whose melting point is higher than that of the second protruding electrode, and a second semiconductor chip that is mounted on the second carrier substrate. The electronic apparatus also includes a mother substrate on which the first carrier substrate is mounted via the first protruding electrode.

This makes it possible to prevent the second protruding electrode, which is bonded to the first carrier substrate, from being melted during mounting of the first carrier substrate on the mother substrate via the first protruding electrode. Furthermore, this also makes it possible to prevent the third protruding electrode, which is bonded to the first carrier substrate, from being melted while mounting the second carrier substrate on the first carrier substrate via the second protruding electrode. Therefore, the deformation of semiconductor packages is prevented during the three-dimensional packaging of semiconductor chips.

A method for manufacturing a semiconductor device according to an aspect of the invention includes the following steps: providing a first protruding electrode for a first semiconductor package, mounting the first semiconductor package on a second semiconductor package via the first protruding electrode, and providing a second protruding electrode whose melting point is lower than that of the first protruding electrode for the second semiconductor package.

This makes it possible to prevent the first protruding electrode, which joins the first and second semiconductor packages, from being melted during mounting of the second semiconductor package via the second protruding electrode. Therefore, the deformation of semiconductor packages is prevented during the three-dimensional packaging of semiconductor chips.

A method for manufacturing a semiconductor device according to an aspect of the invention includes the following steps: providing a third protruding electrode for a first semiconductor chip, mounting the first semiconductor chip on a first carrier substrate via the third protruding electrode, mounting a second semiconductor chip on a second carrier substrate, providing a second protruding electrode whose melting point is lower than that of the third protruding electrode for the second carrier substrate, mounting the second carrier substrate that includes the second semiconductor chip on the first carrier substrate via the second protruding electrode, and providing a first protruding electrode whose melting point is lower than that of the second protruding electrode for the first carrier substrate.

This makes it possible to prevent the third protruding electrode, which joins the first semiconductor chip with the first carrier substrate, from being melted while mounting the second carrier substrate on the first carrier substrate via the second protruding electrode. Furthermore, it is also possible to prevent the second protruding electrode, which joins the first and second carrier substrates, from being melted during mounting of the first carrier substrate via the first protruding electrode. Therefore, the deformation of semiconductor packages is prevented during the three-dimensional packaging of semiconductor chips.

A method for manufacturing an electronic device according to an aspect of the invention includes the following steps: providing a second protruding electrode for a first package that includes a first electronic part, mounting the first package on a second package that includes a second electronic part via the second protruding electrode, and providing a first protruding electrode whose melting point is lower than that of the second protruding electrode for the second package.

This makes it possible to prevent the second protruding electrode, which joins the first and second semiconductor packages, from being melted during mounting of the second package via the first protruding electrode. Therefore, the deformation of packages is prevented during the three-dimensional packaging of electronic parts.

A method for manufacturing an electronic device according to an aspect of the invention includes the following steps: providing a third protruding electrode for a first electronic part, mounting the first electronic part on a first carrier substrate via the third protruding electrode, mounting a second electronic part on a second carrier substrate, providing a second protruding electrode whose melting point is lower than that of the third protruding electrode for the second carrier substrate, mounting the second carrier substrate that includes the second electronic part on the first carrier substrate via the second protruding electrode, and providing a first protruding electrode whose melting point is lower than that of the second protruding electrode for the first carrier substrate.

This makes it possible to prevent the third protruding electrode, which joins the first electronic part with the first carrier substrate, from being melted while mounting the second carrier substrate on the first carrier substrate via the second protruding electrode. Furthermore, it is also possible to prevent the second protruding electrode, which joins the first and second carrier substrates, from being melted during mounting of the first carrier substrate via the first protruding electrode. Therefore, the deformation of packages is prevented during the three-dimensional packaging of electronic parts.

### BRIEF DESCRIPTION OF THE DRAWINGS

FIGS. 1A-1E are sectional views showing a method for manufacturing a semiconductor device according to a first embodiment of the invention.

FIGS. 2A-2C are sectional views showing a method for manufacturing a semiconductor device according to a second embodiment of the invention.

FIGS. 3A-3D are sectional views showing the method for manufacturing the semiconductor device according to the second embodiment of the invention.

### DETAILED DESCRIPTION

A semiconductor device, an electronic device, and methods for manufacturing the devices according to the invention will now be described by referring to the accompanying drawings.

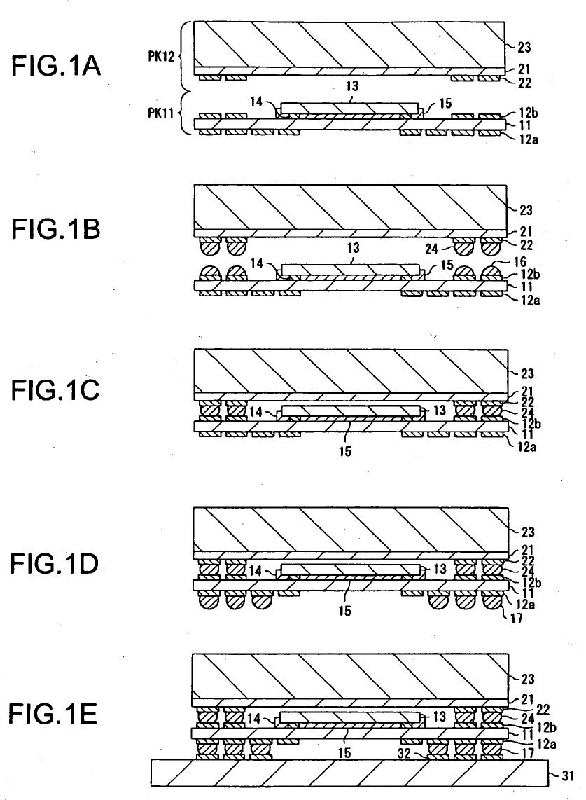

FIGS. 1A-1E are sectional views showing a method for manufacturing a semiconductor device according to a first embodiment of the invention. According to the first embodiment, the melting point of a protruding electrode 24 that is provided in a semiconductor package PK12 is set higher than the melting point of a protruding electrode 17 that is provided in a semiconductor package PK11.

Referring to FIG. 1A, the semiconductor package PK11 includes a carrier substrate 11. On both sides of the carrier substrate 11, lands 12a and 12b are formed. On top of the carrier substrate 11, a semiconductor chip (or a semiconductor die) 13 is flip-chip mounted. The semiconductor chip 13 is provided with a protruding electrode 14 for flip-chip mounting. The protruding electrode 14 provided on the semiconductor chip 13 is bonded onto the land 12b via an anisotropic conductive film (ACF) 15 for bonding.

By using the ACF bonding for mounting the semiconductor chip 13 on the carrier substrate 11, there is no need to spare space for wire bonding and mold sealing. Therefore, it is possible not only to save space when employing three-dimensional packaging, but also to mount the semiconductor chip 13 on the carrier substrate 11 at low temperature. This further prevents the carrier substrate 11 from being curved.

The semiconductor package PK12 includes a carrier substrate 21. On the back surface of the carrier substrate 21, a land 22 is formed. A semiconductor chip is mounted on the carrier substrate 21. The surface of the carrier substrate 21 on which the chip is mounted is wholly covered by sealing resin 23. Here, the semiconductor chip mounted on the carrier substrate 21 is sealed with the sealing resin 23, for example, by means of molding using thermosetting resin such as epoxy resin.

The sealing resin 23 for sealing a semiconductor chip improves the strength of the semiconductor package PK12. This makes it possible to prevent the carrier substrate 21, on which the chip is mounted, from being curved without increasing the height of the semiconductor package PK12.

Here, the semiconductor chip may be mounted on the carrier substrate 21 by using wire bonding or flip-chip bonding. Alternatively, semiconductor chips arranged in a multi-layered structure may be mounted on the carrier substrate 21.

Next, as shown in FIG. 1B, the protruding electrode 24 is provided on the land 22, which is formed on the back-surface of the carrier substrate 21. Meanwhile, flux 16 is provided onto the land 12b, which is formed on the carrier substrate 11. Instead of the flux 16, solder paste may be provided onto the land 12b on the carrier substrate 11.

Then, the semiconductor package PK12 is mounted on the semiconductor package PK11 as shown in FIG. 1C. Subsequently, the protruding electrode 24 is bonded on the land 12b by reflow processing. Here, the protruding electrode 24 is mounted in an area offset from where the semiconductor chip 13 is mounted. For example, the protruding electrode 24 is arranged in the rim area on the back surface of the carrier substrate 21. By bonding the protruding electrode 24 on the land 12b, which is formed on the carrier substrate 11, so as to lay the carrier substrate 21 on the semiconductor chip 13, the carrier substrate 21 is mounted on the carrier substrate 11.

Accordingly, semiconductor chips can be arranged in a multi-layered structure, even if the semiconductor packages PK11 and PK12 are different types. In other words, it is possible to save space with semiconductor chips of different types arranged in a multi-layered structure. When mounting the carrier substrate 21 on the carrier substrate 11, the back surface of the carrier substrate 21 may be either in contact with the semiconductor chip 13 or spaced apart from the semiconductor chip 13.

Next, as shown in FIG. 1D, the protruding electrode 17, whose melting point is lower than that of the protruding electrode 24, is provided on the land 12a, which is formed on the back surface of the carrier substrate 11.

Then, as shown in FIG. 1E, the carrier substrate 11, on which the protruding electrode 17 is formed, is mounted on a mother substrate 31. Subsequently, the protruding electrode 17 is bonded on a land 32 of the mother substrate 31 by reflow processing at a temperature that is lower than the melting point of the protruding electrode 24 and higher than the melting point of the protruding electrode 17.

This makes it possible to prevent the protruding electrode 24, which is bonded on the semiconductor package PK11, from being melted during mounting of the semiconductor package PK11 via the protruding electrode 17. Therefore, the deformation of the semiconductor packages PK11 and PK12 can be prevented during the three-dimensional packaging of semiconductor chips. Accordingly, it is possible to save space when employing the three-dimensional packaging of semiconductor chips, as well as provide a reliable multi-layered structure of the semiconductor chips.

As the carrier substrates 11 and 21, for example, a double-sided substrate, a multi-layered circuit board, a build-up substrate, a tape substrate, a film substrate and the like can be used. As examples of a material of the carrier substrates 11 and 21, polyimide resin, glass epoxy resin, BT resin, aramid-epoxy composite, and ceramic are named. As examples of the protruding electrodes 14, 17, and 24, for example, Au bumps, solder-covered Cu or Ni bumps, and solder balls can be used. In particular, when solder balls are used as the protruding electrodes 17 and 24, a generic ball grid array package (BGA) can be used to form a multi-layered structure of the semiconductor packages PK11 and PK12 that are different types, which means that existing production lines can be utilized.

Among various types of solder balls, each of the protruding electrodes 17 and 24 can be made of Pb—Sn solder of different component ratios. For example, Pb—Sn solder that consists of tin and lead in the proportion of 4 to 6 and whose melting point is 238° C. can be used as the protruding electrode 17, while the protruding electrode 24 can use Pb—Sn solder that consists of tin and lead in the proportion of 2 to 8 and whose melting point is 279° C. Alternatively, each of the protruding electrodes 17 and 24 can be made of lead-free solder of different component ratios. For example, lead-free Sn-3.5Ag-0.75Cu solder whose melting point is 219° C. can be used as the protruding electrode 17, while the protruding electrode 24 can use lead-free Sn-0.75Cu solder whose melting point is 229° C.

The above-mentioned embodiment shows an example in which the protruding electrode 24 is provided on the land 22 formed on the carrier substrate 21 to mount the carrier substrate 21 on the carrier substrate 11. Alternatively, the protruding electrode 24 may be provided on the land 12b formed on the carrier substrate 11. Also in the embodiment, the semiconductor chip 13 is mounted on the carrier substrate 11 by using ACF bonding. Alternatively, other adhesive bonding, such as nonconductive film (NCF) bonding, anisotropic conductive paste (ACP) bonding, and nonconductive paste (NCP) bonding, can be used. Solder bonding and metal bonding such as alloy bonding can also be used. Here, resin may be injected as required in a gap between the carrier substrate 11 and the carrier substrate 21.

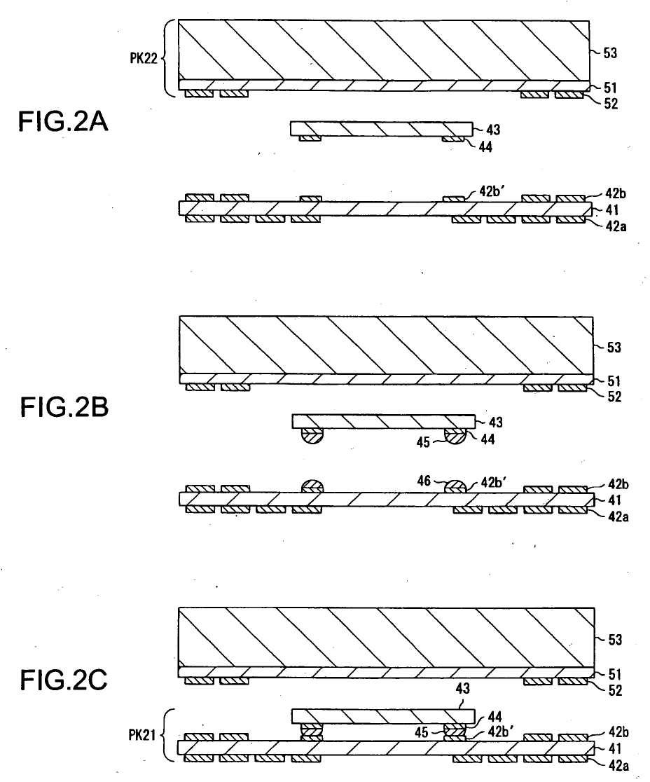

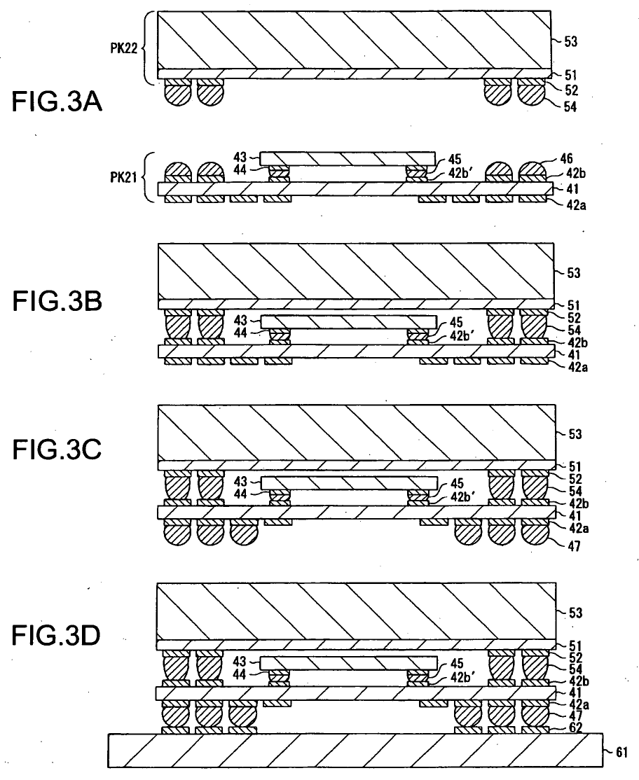

FIGS. 2A-2C and 3A-3D are sectional views showing a method for manufacturing a semiconductor device according to a second embodiment of the invention. According to the second embodiment, the melting point of a protruding electrode 54 that is provided in a semiconductor package PK22 is set higher than the melting point of a protruding electrode 47 that is provided in a semiconductor package PK21. Furthermore, the melting point of a protruding electrode 45 that is provided on a semiconductor chip 43 is set higher than the melting point of the protruding electrode 54 that is provided in the semiconductor package PK22.

Referring to FIG. 2A, lands 42b and 42b′ are formed on a carrier substrate 41, while a land 42a is formed on the back surface of the carrier substrate 41. Also, the semiconductor chip 43 is provided with a land 44 for mounting the protruding electrode 45.

The semiconductor package PK22 includes a carrier substrate 51. On the back surface of the carrier substrate 51, a land 52 is formed. Also, a semiconductor chip is mounted on the carrier substrate 51. The surface of the carrier substrate 51 on which the chip is mounted is wholly covered by sealing resin 53. Here, the semiconductor chip mounted on the carrier substrate 51 is sealed with the sealing resin 53, for example, by means of molding using thermosetting resin such as epoxy resin. The semiconductor chip may be mounted on the carrier substrate 51 by using wire bonding or flip-chip bonding. Alternatively, semiconductor chips arranged in a multi-layered structure may be mounted on the carrier substrate 51.

Next, as shown in FIG. 2B, the protruding electrode 45 is provided on the land 44, which is provided on the semiconductor chip 43. Here, the protruding electrode 45 may be provided on the carrier substrate 41 instead. Flux 46 is provided onto the land 42b′ on the carrier substrate 41. Instead of the flux 46, solder paste may be provided onto the land 42b′ on the carrier substrate 41.

Then, as shown in FIG. 2C, the semiconductor chip 43 is mounted on the carrier substrate 41. Subsequently, the protruding electrode 45 is bonded on the land 42b′ by reflow processing to form the semiconductor package PK21.

Next, as shown in FIG. 3A, the protruding electrode 54, whose melting point is lower than that of the protruding electrode 45, is provided on the land 52, which is formed on the back surface of the carrier substrate 51. Here, the protruding electrode 54 may be provided on the carrier substrate 41 instead. Flux 46 is provided onto the land 42b, which is formed on the carrier substrate 41. Instead of the flux 46, solder paste may be provided onto the land 42b on the carrier substrate 41.

Then, as shown in FIG. 3B, the semiconductor package PK22 is mounted on the semiconductor package PK21. Subsequently, the protruding electrode 54 is bonded on the land 42b by reflow processing at a temperature that is lower than the melting point of the protruding electrode 45 and higher than the melting point of the protruding electrode 54. Here, the protruding electrode 54 is mounted in an area offset from where the semiconductor chip 43 is mounted. For example, the protruding electrode 54 is arranged in the rim area on the back surface of the carrier substrate 51. By bonding the protruding electrode 54 on the land 42b, which is formed on the carrier substrate 41 so as to lay the carrier substrate 51 on the semiconductor chip 43, the carrier substrate 51 is mounted on the carrier substrate 41.

Accordingly, semiconductor chips can be arranged in a multi-layered structure, even if the semiconductor packages PK21 and PK22 are different types. In other words, it is possible to save space with semiconductor chips of different types arranged in a multi-layered structure.

Next, as shown in FIG. 3C, the protruding electrode 47, whose melting point is lower than that of the protruding electrode 54, is provided on the land 42a, which is formed on the back surface of the carrier substrate 41.

Then, as shown in FIG. 3D, the carrier substrate 41, on which the protruding electrode 47 is formed, is mounted on a mother substrate 61. Subsequently, the protruding electrode 47 is bonded on a land 62 formed on the mother substrate 61 by reflow processing at a temperature that is lower than the melting point of the protruding electrode 54 and higher than the melting point of the protruding electrode 47.

This makes it possible to prevent the protruding electrode 45, which joins the semiconductor chip 43 with the carrier substrate 41, from being melted while mounting the carrier substrate 51 on the carrier substrate 41 via the protruding electrode 54. Furthermore, this also makes it possible to prevent the protruding electrode 54, which joins the carrier substrate 51 with the carrier substrate 41, from being melted while mounting the carrier substrate 41 on the mother substrate 61 via the protruding electrode 47. Therefore, the deformation of the semiconductor packages PK21 and PK22 can be prevented during the three-dimensional packaging of semiconductor chips.

As the protruding electrodes 45, 47, and 54, for example, Au bumps, solder-covered Cu or Ni bumps, and solder balls can be used. Here, resin may be injected as required in a gap between the carrier substrate 41 and the carrier substrate 51.

The semiconductor and electronic devices according to the embodiments described herein can be used for an electronic apparatus, such as a liquid crystal display, a mobile phone, a personal digital assistant, a video camera, a digital camera, a mini disc (MD) player, and the like. The devices make it possible to provide a smaller and lighter electronic apparatus, and at the same time, improve the reliability of such an electronic apparatus.

What is claimed is:

1. A semiconductor device, comprising:
a first semiconductor package that includes a first semiconductor chip;
a first protruding electrode bonded to the first semiconductor package; and
a second semiconductor package that includes a second semiconductor chip, the second semiconductor package being mounted on the first semiconductor package via a second protruding electrode, the second protruding electrode having a melting point which is higher than a melting point of the first protruding electrode.

2. The semiconductor device according to claim 1, wherein:
the first semiconductor package further includes a first carrier substrate on which the first semiconductor chip is mounted, and
the second semiconductor package further includes a second carrier substrate that is mounted on the first carrier substrate via the second protruding electrode so as to lay the second carrier substrate on the first semiconductor chip.

3. The semiconductor device according to claim 2, wherein:
the first semiconductor package further includes a ball grid array package having the first semiconductor chip that is flip-chip mounted on the first carrier substrate, and
the second semiconductor package further includes any one of a ball grid array package and a chip size package having the second semiconductor chip that is mounted and sealed by means of molding on the second carrier substrate.

4. A semiconductor device, comprising:
a first carrier substrate;
a first protruding electrode bonded to the first carrier substrate;
a second carrier substrate that is mounted on the first carrier substrate via a second protruding electrode, the second protruding electrode having a melting point that is higher than a melting point of the first protruding electrode;
a first semiconductor chip that is mounted on the first carrier substrate via a third protruding electrode, the third protruding electrode having a melting point that is higher than the melting point of the second protruding electrode; and
a second semiconductor chip that is mounted on the second carrier substrate.

5. An electronic device, comprising:
a first package that includes a first electronic part;
a first protruding electrode bonded to the first package; and
a second package that includes a second electronic part, the second package being mounted on the first package via a second protruding electrode, the second protruding electrode having a melting point that is higher than a melting point of the first protruding electrode.

6. An electronic device, comprising:
a first carrier substrate;
a first protruding electrode bonded to the first carrier substrate;
a second carrier substrate that is mounted on the first carrier substrate via a second protruding electrode, the second protruding electrode having a melting point that is higher than a melting point of the first protruding electrode;
a first electronic part that is mounted on the first carrier substrate via a third protruding electrode, the third protruding electrode having a melting point that is higher than the melting point of the second protruding electrode; and
a second electronic part that is mounted on the second carrier substrate.

7. An electronic apparatus, comprising:
a first semiconductor package that includes a first semiconductor chip;
a first protruding electrode that is bonded to the first semiconductor package;
a second semiconductor package that includes a second semiconductor chip, the second semiconductor package being mounted on the first semiconductor package via a second protruding electrode, the second protruding electrode having a melting point that is higher than a melting point of the first protruding electrode; and
a mother substrate on which the first semiconductor package is mounted via the first protruding electrode.

8. An electronic apparatus, comprising:
a first carrier substrate;
a first protruding electrode that is bonded to the first carrier substrate;
a second carrier substrate that is mounted on the first carrier substrate via a second protruding electrode, the second protruding electrode having a melting point that is higher than a melting point of the first protruding electrode;
a first semiconductor chip that is mounted on the first carrier substrate via a third protruding electrode, the third protruding electrode having a melting point that is higher than the melting point of the second protruding electrode;
a second semiconductor chip that is mounted on the second carrier substrate; and
a mother substrate on which the first carrier substrate is mounted via the first protruding electrode.

9. A method for manufacturing a semiconductor device, comprising:
providing a first protruding electrode for a first semiconductor package;
mounting the first semiconductor package on a second semiconductor package via the first protruding electrode; and
providing a second protruding electrode for the second semiconductor package, the second protruding electrode having a melting point that is lower than a melting point of the first protruding electrode.

10. A method for manufacturing a semiconductor device, comprising:
providing a third protruding electrode for a first semiconductor chip;
mounting the first semiconductor chip on a first carrier substrate via the third protruding electrode;
mounting a second semiconductor chip on a second carrier substrate;
providing a second protruding electrode for the second carrier substrate, the second protruding electrode having a melting point that is lower than a melting point of the third protruding electrode;
mounting the second carrier substrate that includes the second semiconductor chip on the first carrier substrate via the second protruding electrode; and
providing a first protruding electrode for the first carrier substrate, the first protruding electrode having a melting point that is lower than the melting point of the second protruding electrode.

11. A method for manufacturing an electronic device, comprising:
providing a second protruding electrode for a first package that includes a first electronic part;
mounting the first package on a second package that includes a second electronic part via the second protruding electrode; and
providing a first protruding electrode for the second package, the first protruding electrode having a melting point that is lower than a melting point of the second protruding electrode.

12. A method for manufacturing an electronic device, comprising:
providing a third protruding electrode to a first electronic part;
mounting the first electronic part on a first carrier substrate via the third protruding electrode;
mounting a second electronic part on a second carrier substrate;
providing a second protruding electrode for the second carrier substrate, the second protruding electrode having a melting point that is lower than a melting point of the third protruding electrode;
mounting the second carrier substrate that includes the second electronic part on the first carrier substrate via the second protruding electrode; and
providing a first protruding electrode for the first carrier substrate, the first protruding electrode having a melting point that is lower than a melting point of the second protruding electrode.
